(19) United States
(12) Patent Application Publication
(10) Pub. No.: US 2022/0186373 A1
(43) Pub. Date: Jun. 16, 2022

(54) SUBSTRATE PROCESSING DEVICE

(71) Applicant: JUSUNG ENGINEERING CO., LTD., Gwangju-si, Gyeonggi-do (KR)

(72) Inventors: JongSik KIM, Gwangju-si, Gyeonggi-do (KR); ChulJoo HWANG, Gwangju-si, Gyeonggi-do (KR)

(21) Appl. No.: 17/436,651

(22) PCT Filed: May 19, 2020
(86) PCT No.: PCT/KR2020/006526

§ 371 Date: Sep. 6, 2021

(30) Foreign Application Priority Data
May 20, 2019 (KR) 10-2019-0058495

(51) Int. Cl. C23C 16/455; C23C 16/44; H01L 21/687; H01J 37/32

(52) U.S. Cl. CPC C23C 16/45548; C23C 16/4408; H01L 21/6875; H01J 37/32009; H01L 21/68764

(57) ABSTRACT

The present disclosure relates to an apparatus for processing substrate including a supporting unit for supporting a substrate, a lid disposed apart from the supporting unit in an upward direction, a first gas injection unit coupled to the lid to inject a first gas into a first region, a second gas injection unit coupled to the lid to inject a second gas into a second region, a purge gas unit coupled to the lid to inject a purge gas into a third region disposed between the first region and the second region, and a rotation unit for rotating the supporting unit.

### TECHNICAL FIELD

The present disclosure relates to a substrate processing apparatus which performs a processing such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing is performed on a substrate, and examples of the processing include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing is performed on a substrate by a substrate processing apparatus.

A substrate processing apparatus of the related art includes a substrate supporting unit which supports a substrate, a rotation unit which continuously rotates the substrate supporting unit with respect to a rotation shaft thereof, a first gas injection unit which injects a first gas toward a first injection space of the substrate supporting unit, and a second gas injection unit which injects a second gas toward a second injection space of the substrate supporting unit.

While the first gas injection unit is injecting the first gas to the first injection space and the second gas injection unit is injecting the second gas to the second injection space, the rotation unit continuously rotates the substrate supporting unit so that the substrate passes through the first injection space and the second injection space sequentially and repeatedly. Therefore, an adsorption process of adsorbing the first gas onto the substrate is performed in the first injection space, and then, the first gas adsorbed onto the substrate reacts with the second gas injected by the second gas injection unit, thereby performing a deposition process of depositing a thin film on the substrate. Accordingly, the thin film is deposited on the substrate by an atomic layer deposition (ALD) process.

Here, the substrate processing apparatus of the related art is implemented so that the rotation unit continuously rotates the substrate supporting unit, and thus, the adsorption process is performed in a state where the substrate is rotating.

Due to this, in the substrate processing apparatus of the related art, due to a centrifugal force which is generated as the substrate rotates continuously, the adsorption process is not normally performed in the first injection space.

Therefore, in the substrate processing apparatus of the related art, the first gas which is not adsorbed onto the substrate in the second injection space reacts with the second gas injected by the second gas injection unit, at an upper portion of the substrate, and thus, the thin film is deposited on the substrate by a chemical vapor deposition (CVD) process, causing a problem where the film quality of the thin film deposited on the substrate is degraded.

### DISCLOSURE

### Technical Problem

The present disclosure is devised to solve the above-described problem and is for providing a substrate processing apparatus for preventing the film quality of a thin film deposited on a substrate from being degraded.

### Technical Solution

To accomplish the above-described object, the present disclosure may include the following elements.

An apparatus for processing substrate according to the present disclosure may include a supporting unit for supporting a substrate, a lid disposed apart from the supporting unit in an upward direction, a first gas injection unit coupled to the lid to inject a first gas into a first region, a second gas injection unit coupled to the lid to inject a second gas into a second region, a purge gas unit coupled to the lid to inject a purge gas into a third region disposed between the first region and the second region, and a rotation unit for rotating the supporting unit. The rotation unit may rotate the supporting unit, so that the substrate moves between the first region and the second region, and may stop the rotation of the supporting unit while a processing using the first gas is being performed in the first region and a processing using the second gas is being performed in the second region. A distance by which a bottom surface of the first gas injection unit is disposed apart from the supporting unit is shorter than a distance by which a bottom surface of the second gas injection unit is apart from the supporting unit.

### Advantageous Effect

According to the present disclosure, the following effects may be obtained.

The present disclosure is implemented so that a substrate moves between a first region and a second region through a rotation of a supporting unit, and simultaneously, a processing using a first gas and a processing using a second gas are performed in a state where the rotation of the supporting unit stops. Accordingly, the present disclosure may enhance the stability of a process of depositing a thin film on the substrate by using an atomic layer deposition (ALD) process, thereby enhancing the film quality of the thin film.

### DESCRIPTION OF DRAWINGS

FIG. 1 is a schematic exploded perspective view of a substrate processing apparatus according to the present disclosure.

FIG. 2 is a schematic side cross-sectional view taken along line I-I of FIG. 1 in the substrate processing apparatus according to the present disclosure.

FIG. 3 is a schematic plan view of a supporting unit in the substrate processing apparatus according to the present disclosure.

FIG. 4 is a schematic plan view of a lid in the substrate processing apparatus according to the present disclosure.

FIG. 5 is a schematic side cross-sectional view taken along line I-I of FIG. 1 in an embodiment where a first gas injection unit and a second gas injection unit are disposed in the substrate processing apparatus according to the present disclosure.

FIGS. 6 and 7 are schematic plan views of an embodiment of an injection module in the substrate processing apparatus according to the present disclosure.

FIG. 8 is a schematic plan cross-sectional view of a purge gas unit taken along line II-II of FIG. 1 in the substrate processing apparatus according to the present disclosure.

FIG. 9 is a schematic side cross-sectional view taken along line I-I of FIG. 1 in an embodiment where a purge gas unit is disposed in the substrate processing apparatus according to the present disclosure.

FIGS. 10 to 12 are schematic plan views of a supporting unit in the substrate processing apparatus according to the present disclosure.

FIG. 13 is a schematic plan cross-sectional view of a supporting unit taken along line of FIG. 12 in the substrate processing apparatus according to the present disclosure.

### MODE FOR INVENTION

Hereinafter, an embodiment of a substrate processing apparatus according to the present disclosure will be described in detail with reference to the accompanying drawings.

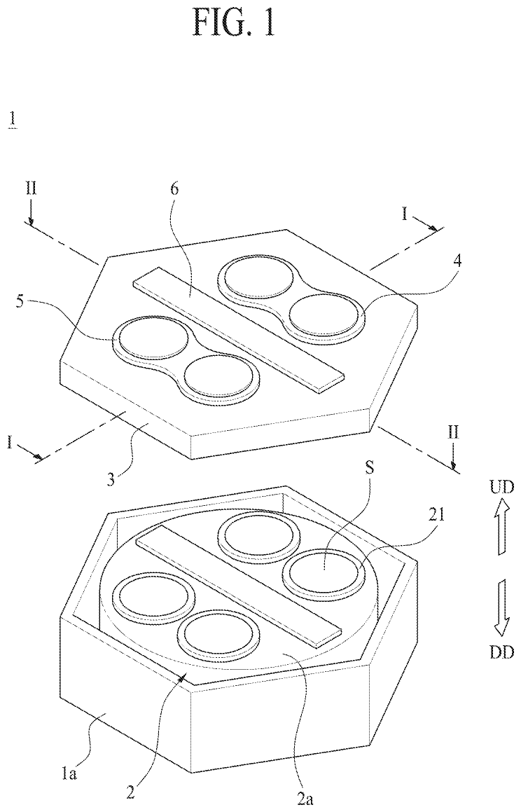

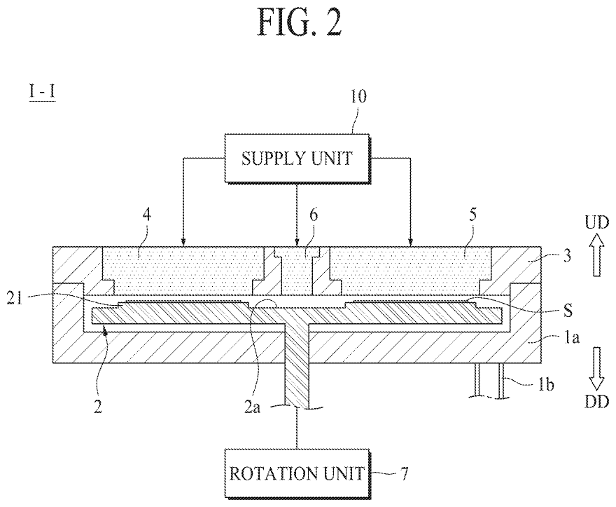

Referring to FIGS. 1 and 2, a substrate processing apparatus 1 according to the present disclosure performs a processing on a substrate S. The substrate S may be a glass substrate, a silicon substrate, a metal substrate, or the like. The substrate processing apparatus 1 according to the present disclosure may perform a deposition process of depositing a thin film on the substrate S and an etching process of removing a portion of the thin film deposited on the substrate S. Hereinafter, an embodiment where the substrate processing apparatus 1 according to the present disclosure performs the deposition process will be described, but it is obvious to those skilled in the art to implement an embodiment where the substrate processing apparatus 1 according to the present disclosure performs another processing such as the etching process.

The substrate processing apparatus 1 according to the present disclosure may include a supporting unit 2, a lid 3, a first gas injection unit 4, a second gas injection unit 5, a purge gas unit 6, and a rotation unit 7.

The supporting unit 2 supports the substrate S. The supporting unit 2 may be coupled to an inner portion of a chamber 1a providing a processing space where the processing is performed. The processing space may be disposed between the supporting unit 2 and the lid 3. A substrate entrance (not shown) may be coupled to the chamber 1a. The substrates S may pass through the substrate entrance and may be loaded into the chamber 1a by using a loading apparatus (not shown). When the processing is completed, the substrates S may pass through the substrate entrance and may be unloaded to the outside of the chamber 1a by using an unloading apparatus (not shown). An exhaust member 1b (illustrated in FIG. 2) for exhausting a gas, which is in the processing space, to the outside may be coupled to the chamber 1a.

The supporting unit 2 may include a mounting member 21 with the substrate S mounted thereon.

The mounting member 21 may be disposed between the supporting unit 2 and the lid 3 and may be coupled to the supporting unit 2. That is, the mounting member 21 may be coupled to a top surface 2a of the supporting unit 2. The substrate S may be mounted on the mounting member 21 to protrude an upward direction (a UD arrow direction) with respect to the mounting member 21. The upward direction (the UD arrow direction) may be a direction from the supporting unit 21 to the lid 3. Although not shown, the mounting member 21 may include a mounting groove (not shown) with the substrate S inserted thereinto. In this case, the substrate S may be inserted into the mounting groove, and thus, may be mounted on the mounting member 21. The mounting member 21 and the supporting unit 2 may be provided as one body.

The mounting member 21 may protrude in the upward direction (the UD arrow direction) from the top surface 2a of the supporting unit 2. Therefore, a top surface of the substrate S may be disposed at a position apart from the top surface 2a of the supporting unit 2 in the upward direction (the UD arrow direction). Accordingly, the substrate processing apparatus 1 according to the present disclosure may implement a restraint force which prevents a gas from penetrating toward the top surface of the substrate S in a process of exhausting the gas from the processing space to the outside of the chamber 1a. Accordingly, the substrate processing apparatus 1 according to the present disclosure may enhance the quality of the substrate S on which the processing is completed.

The supporting unit 2 may include the mounting member 21 provided in plurality. Therefore, the supporting unit 2 may be implemented to support the substrate S provided in plurality. The mounting members 21 may be disposed apart from one another. Accordingly, the substrates S may be disposed apart from one another.

Referring to FIGS. 1 and 2, the lid 3 is disposed apart from the supporting unit 2 in the upward direction (the UD arrow direction). The lid 3 may be coupled to the chamber 1a to cover an upper portion of the chamber 1a. The lid 3 and the chamber 1a may be implemented in a hexagonal structure as illustrated in FIG. 1, but is not limited thereto and may be implemented in a polygonal structure such as a cylindrical structure, an oval structure, or an octagonal structure.

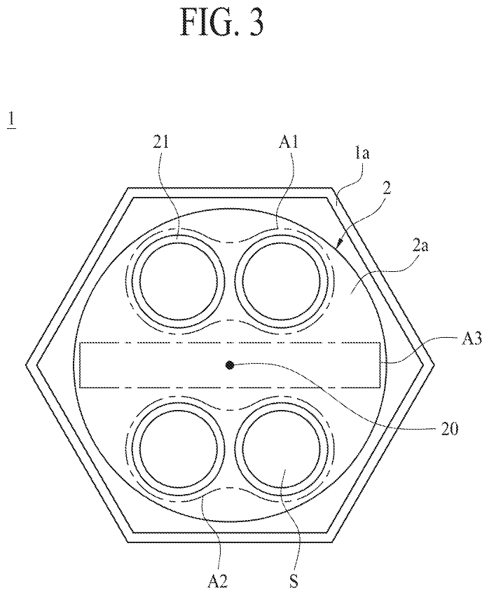

Referring to FIGS. 1 to 5, the first gas injection unit 4 injects a first gas. The first gas injection unit 4 may be coupled to the lid 3 and may be apart from the supporting unit 2 in the upward direction (the UD arrow direction). The first gas injection unit 4 may inject the first gas through a plurality of first injection holes. The first gas injection unit 4 may inject the first gas into a first region A1 (illustrated in FIG. 3). Therefore, a processing using the first gas may be performed in the first region A1. The first region A1 may be a region into which the first gas is injected and may be a region disposed between the supporting unit 2 and the first gas injection unit 4. A bottom surface 4a of the first gas injection unit 4 may be disposed in the upward direction (the UD arrow direction) with respect to the first region A1. The bottom surface 4a of the first gas injection unit 4 may be a surface of the first gas injection unit 4 in a downward direction (a DD arrow direction). The downward direction (the DD arrow direction) may be opposite to the upward direction (the UD arrow direction). The first gas injection unit 4 may be connected to a supply unit 10 (illustrated in FIG. 2) through a hose, a pipe, and/or the like. The supply unit 10 supplies the first gas. The first gas may be a precursor constituting a source material of the thin film deposited on the substrate S.

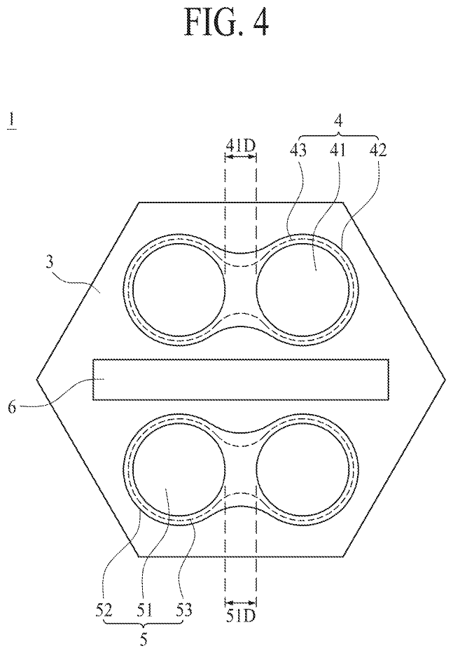

The first gas injection unit 4 may include a first injection module 41 (illustrated in FIG. 4) which injects the first gas.

The first injection module 41 injects the first gas into the first region A1. The first injection module 41 may inject the first gas into the first region A1 through the first injection holes. The first injection module 41 may be coupled to a first injection body 42 (illustrated in FIG. 4) included in the first gas injection unit 4. The first injection body 42 is coupled to the lid 3. The first injection module 41 may be coupled to the lid 3 through the first injection body 42. The first injection module 41 may be provided to have a size which is greater than that of the substrate S.

The first injection module 41 provided in plurality may be coupled to the first injection body 42. In this case, the plurality of substrates S may be disposed in the first region A1. Therefore, the substrate processing apparatus 1 according to the present disclosure may perform a processing on the plurality of substrates S in the first region A1 by using the first gas injected by each of the plurality of first injection modules 41, thereby increasing a processing rate of a processing using the first gas. 2N (where N is an integer more than 0) number of first injection modules 41 may be coupled to the first injection body 42.

The first gas injection unit 4 may include a first sealing member 43 (illustrated in FIG. 4).

The first sealing member 43 seals a gap between the first injection body 42 and the lid 3. When a plurality of first injection modules 41 are coupled to the first injection body 42, the first sealing member 43 may be disposed to surround outer portions of the first injection modules 41. That is, the first injection modules 41 may be disposed inward from the first sealing member 43. Therefore, in the substrate processing apparatus 1 according to the present disclosure, the first sealing member 43 may not be located between the first injection modules 41, thereby decreasing an interval 41D (illustrated in FIG. 4) between the first injection modules 41. Accordingly, a size of the first gas injection unit 4 may be reduced, and thus, the substrate processing apparatus 1 according to the present disclosure may be implemented to enable the implementation of a wholly miniaturized size.

Referring to FIGS. 1 to 5, the second gas injection unit 5 injects a second gas. The second gas injection unit 5 may be coupled to the lid 3 and may be apart from the supporting unit 2 in the upward direction (the UD arrow direction). With respect to the purge gas unit 6, the second gas injection unit 5 may be disposed to be opposite to the first gas injection unit 4.

The second gas injection unit 5 may inject the second gas through a plurality of second injection holes. The second gas injection unit 5 may inject the second gas into a second region A2 (illustrated in FIG. 3). Therefore, a processing using the second gas may be performed in the second region A2. The second region A2 may be a region into which the second gas is injected and may be a region disposed between the supporting unit 2 and the second gas injection unit 5. A bottom surface 5a of the second gas injection unit 5 may be disposed in the upward direction (the UD arrow direction) with respect to the second region A2. The bottom surface 5a of the second gas injection unit 5 may be a surface of the second gas injection unit 5 in the downward direction (the DD arrow direction). The second region A2 may be disposed at a position apart from the first region A1. The second gas injection unit 5 may be connected to the supply unit 10 (illustrated in FIG. 2) through a hose, a pipe, and/or the like. Although not shown, the supply unit 10 may include a first supply mechanism which supplies the first gas and a second supply mechanism which supplies the second gas. The first supply mechanism may be connected to the first gas injection unit 4 and may supply the first gas to the first gas injection unit 4. The second supply mechanism may be connected to the second gas injection unit 5 and may supply the second gas to the second gas injection unit 5. When the first gas is a source gas, the second gas may be a reactant gas.

The second gas injection unit 5 may include a second injection module 51 (illustrated in FIG. 4) which injects the second gas.

The second injection module 51 injects the second gas into the second region A2. The second injection module 51 may inject the second gas into the second region A2 through the second injection holes. The second injection module 51 may be coupled to a second injection body 52 (illustrated in FIG. 4) included in the second gas injection unit 5. The second injection body 52 is coupled to the lid 3. The second injection module 51 may be coupled to the lid 3 through the second injection body 52. The second injection module 51 may be provided to have a size which is greater than that of the substrate S.

The second injection module 51 provided in plurality may be coupled to the second injection body 52. In this case, the plurality of substrates S may be disposed in the second region A2. Therefore, the substrate processing apparatus 1 according to the present disclosure may perform a processing on the plurality of substrates S in the second region A2 by using the second gas injected by each of the plurality of second injection modules 51, thereby increasing a processing rate of a processing using the second gas. 2N number of second injection modules 51 may be coupled to the second injection body 52. The second injection module 51 and the first injection module 41 may be provided as the same number.

The second gas injection unit 5 may include a second sealing member 53 (illustrated in FIG. 4).

The second sealing member 53 seals a gap between the second injection body 52 and the lid 3. When a plurality of second injection modules 51 are coupled to the second injection body 52, the second sealing member 53 may be disposed to surround outer portions of the second injection modules 51. That is, the second injection modules 51 may be disposed inward from the second sealing member 53. Therefore, in the substrate processing apparatus 1 according to the present disclosure, the second sealing member 53 may not be located between the second injection modules 51, thereby decreasing an interval 51D (illustrated in FIG. 4) between the second injection modules 51. Accordingly, a size of the second gas injection unit 5 may be reduced, and thus, the substrate processing apparatus 1 according to the present disclosure may be implemented to enable the implementation of a wholly miniaturized size.

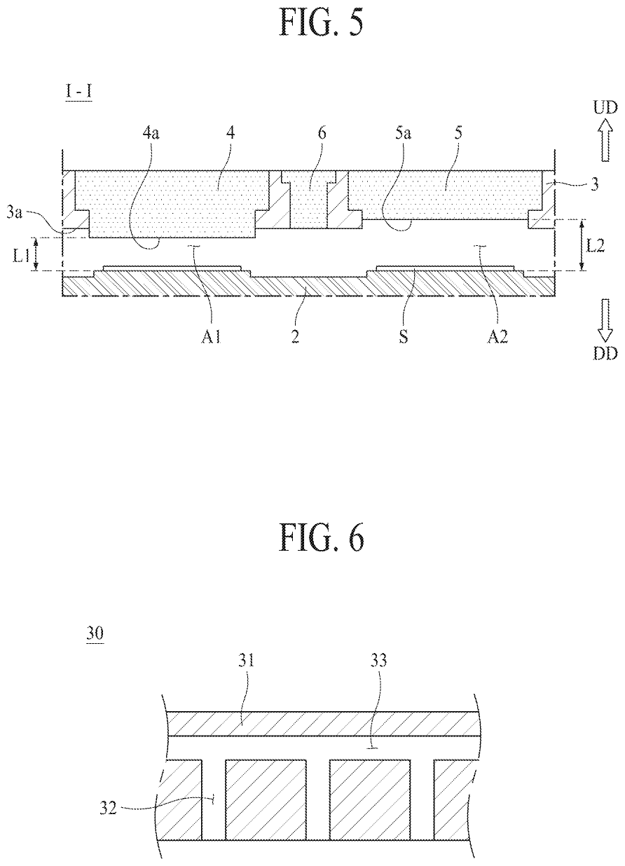

Referring to FIG. 5, the bottom surface 5a of the second gas injection unit 5 may be disposed apart from the supporting unit 2 by a distance which is longer than a distance by which the bottom surface 4a of the first gas injection unit 4 is apart from the supporting unit 2. For example, a first separation distance L1 by which the bottom surface 4a of the first gas injection unit 4 is apart from the supporting unit 2 may be set to be shorter than a second separation distance L2 by which the bottom surface 5a of the second gas injection unit 5 is apart from the supporting unit 2. Therefore, the substrate processing apparatus 1 according to the present disclosure may be implemented to decrease a partial pressure difference between the first region A1 and the second region A2 even when a flow rate of the second gas injected through the second gas injection unit 5 is higher than that of the first gas injected through the first gas injection unit 4. A partial pressure denotes pressure represented by each component gas in a mixed gas, is proportional to a flow rate of a gas, and is inversely proportional to a size of a region into which a gas is injected. Accordingly, in the substrate processing apparatus 1 according to the present disclosure, the second region A2 may be formed to have a greater size than that of the first region A1, thereby decreasing a partial pressure difference between the first region A1 and the second region A2 even when the second gas is injected at a flow rate which is higher than that of the first gas. Therefore, the substrate processing apparatus 1 according to the present disclosure may prevent the first gas from penetrating into the second region A2 and may prevent the second gas from penetrating the first region A1 in a processing using the first gas and the second gas, and thus, may enhance a level of completion of the processing using the first gas in the first region A1 and may enhance a level of completion of the processing using the second gas in the second region A2. Accordingly, the substrate processing apparatus 1 according to the present disclosure may prevent film quality from being degraded due to mixing of the first gas and the second gas, thereby enhancing the quality of a substrate on which a processing is completed.

Referring to FIG. 5, the bottom surface 5a of the second gas injection unit 5 may be disposed apart from a bottom surface 3a of the lid 3 in the upward direction (the UD arrow direction). In this case, the bottom surface 4a of the first gas injection unit 4 may be disposed apart from the bottom surface 3a of the lid 3 in the downward direction (the DD arrow direction). Therefore, since the second region A2 is implemented to have a greater size than that of the first region A1, the substrate processing apparatus 1 according to the present disclosure may decrease a partial pressure difference between the first region A1 and the second region A2 even when the second gas is injected to the supporting unit 2 at a flow rate which is higher than that of the first gas. The bottom surface 3a of the lid 3 may be a surface of the lid 3 in the downward direction (the DD arrow direction).

Although not shown, when the bottom surface 5a of the second gas injection unit 5 is disposed apart from the bottom surface 3a of the lid 3 in the upward direction (the UD arrow direction), the bottom surface 4a of the first gas injection unit 4 may be disposed at the same height as the bottom surface 3a of the lid 3. Accordingly, since the second region A2 is implemented to have a greater size than that of the first region A1, the substrate processing apparatus 1 according to the present disclosure may decrease a partial pressure difference between the first region A1 and the second region A2.

The bottom surface 5a of the second gas injection unit 5 may be disposed apart from the supporting unit 2 by a distance which is 3 to 15 times a distance by which the bottom surface 4a of the first gas injection unit 4 is apart from the supporting unit 2. In this case, a distance by which the bottom surface 5a of the second gas injection unit 5 is apart from the supporting unit 2 may be equal to or less than a distance which is 3 to 15 times a distance by which the bottom surface 4a of the first gas injection unit 4 is apart from the supporting unit 2. For example, the first separation distance L1 may be set to more than 0 mm and 5 mm or less, and the second separation distance L2 may be set to 3 mm to 15 mm Therefore, since the second region A2 is implemented to have a greater size than that of the first region A1, the substrate processing apparatus 1 according to the present disclosure may decrease a partial pressure difference between the first region A1 and the second region A2 even when the second gas is injected to the supporting unit 2 at a flow rate which is higher than that of the first gas.

The second gas injection unit 5 may inject the second gas into the second region A2 having a greater volume than that of the first region A1 into which the first gas injection unit 4 injects the first gas. Therefore, the substrate processing apparatus 1 according to the present disclosure may decrease a partial pressure difference between the first region A1 and the second region A2 even when the second gas is injected to the supporting unit 2 at a flow rate which is higher than that of the first gas, and thus, may prevent the first gas from penetrating into the second region A2 and may prevent the second gas from penetrating the first region A1.

An embodiment of an injection module 30 corresponding to the second injection module 51 (illustrated in FIG. 4) and the first injection module 41 (illustrated in FIG. 4) will be described below in detail with reference to FIGS. 4 to 7.

As illustrated in FIG. 6, the injection module 30 may include a module body 31, a plurality of injection holes 32 injecting a gas toward the supporting unit 2, and a transfer hole 33 connected to the injection holes 32. The transfer hole 33 may be connected to the supply unit 10 (illustrated in FIG. 2). Therefore, a gas supplied by the supply unit 10 (illustrated in FIG. 2) may be injected to the supporting unit 2 through the injection holes 32 while flowing along the transfer hole 33. Although not shown, a plasma generating unit may be connected to the injection module 30. In this case, the injection module 30 may activate the gas by using the plasma and may inject the activated gas toward the supporting unit 2.

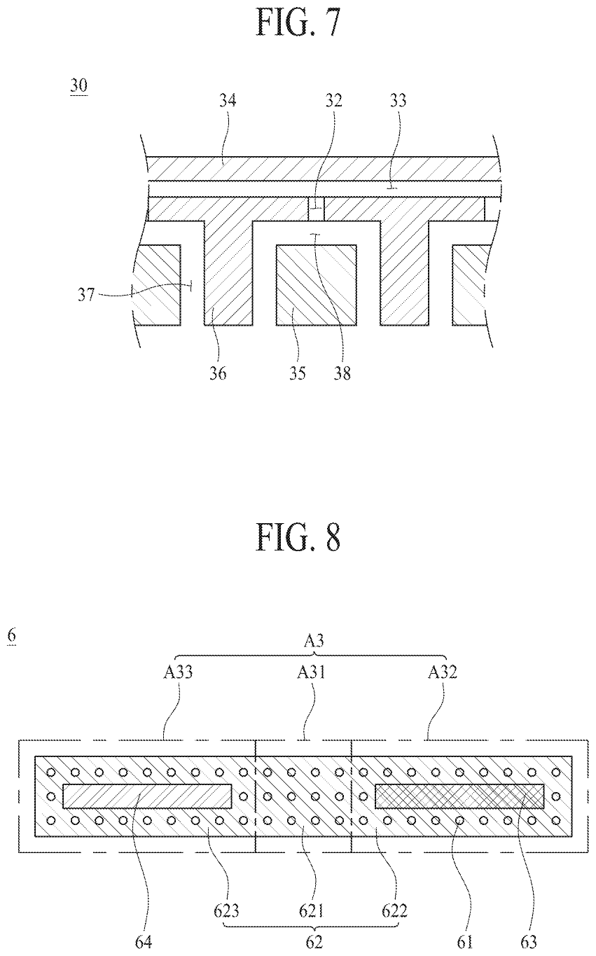

As illustrated in FIG. 7, the injection module 30 may include a first electrode 34 and a second electrode 35. A plurality of protrusion electrodes 36 may be formed in the first electrode 34. A plurality of electrode holes 37 may be formed in the second electrode 35. The first electrode 34 and the second electrode 35 may be disposed so that the protrusion electrodes 36 are respectively inserted into the electrode holes 37. In this case, the injection holes 32 and the transfer holes 33 may be formed in the first electrode 34. When the protrusion electrodes 36 are grounded and a plasma power is applied to the second electrode 35, the injection module 30 may generate plasma. Therefore, the injection module 30 may activate a gas in a separation space 38 formed between the first electrode 34 and the second electrode 35 by using the plasma. A gas which has sequentially moved through the transfer hole 33 and the injection hole 32 may be activated in the separation space 38 and may be injected toward the supporting unit 2.

The first gas injection unit 4 and the second gas injection unit 5 may be implemented to include different kinds of injection modules 30. For example, the first gas injection unit 4 may include a showerhead type injection module 30 illustrated in FIG. 6, and the second gas injection unit 5 may include an electrode structure type injection module 30 illustrated in FIG. 7. For example, the first gas injection unit 4 may include the electrode structure type injection module 30 illustrated in FIG. 7, and the second gas injection unit 5 may include the showerhead type injection module 30 illustrated in FIG. 6.

When the first gas injection unit 4 includes the showerhead type injection module 30 and the second gas injection unit 5 includes the electrode structure type injection module 30, the substrate processing apparatus 1 according to the present disclosure may be implemented so that the second gas injection unit 5 injects the second gas into the separation space 38. Accordingly, the substrate processing apparatus 1 according to the present disclosure may be implemented so that an additional injection space for the second gas is secured through the separation space 38, and thus, a partial pressure difference between the first region A1 and the second region A2 is reduced even when a flow rate of the second gas increases.

The first gas injection unit 4 and the second gas injection unit 5 may be implemented to include the same kind of injection module 30. For example, each of the first gas injection unit 4 and the second gas injection unit 5 may include the showerhead type injection module 30 illustrated in FIG. 6. For example, each of the first gas injection unit 4 and the second gas injection unit 5 may include the electrode structure type injection module 30 illustrated in FIG. 7.

Referring to FIGS. 1 to 10, the purge gas unit 6 injects a purge gas. The purge gas unit 6 may inject the purge gas into a third region 3, and thus, may divide the first region A1 and the second region A2. Therefore, the purge gas unit 6 may prevent the first gas injected into the first region A1 from being mixed with the second gas injected into the second region A2. The third region A3 may be disposed between the first region A1 and the second region A2. The third region A3 may be a region into which the purge gas is injected and may be a region disposed between the supporting unit 2 and the purge gas unit 6. A bottom surface 6a of the purge gas unit 6 may be disposed in the upward direction (the UD arrow direction) with respect to the third region A3. The bottom surface 6a of the purge gas unit 6 may be a surface of the purge gas unit 6 in the downward direction (the DD arrow direction). The purge gas unit 6 may be connected to the supply unit 10 (illustrated in FIG. 2) through a hose, a pipe, and/or the like. Although not shown, the supply unit 10 may include a third supply mechanism which supplies the purge gas. The third supply mechanism may be connected to the purge gas unit 6 and may supply the purge gas to the purge gas unit 6.

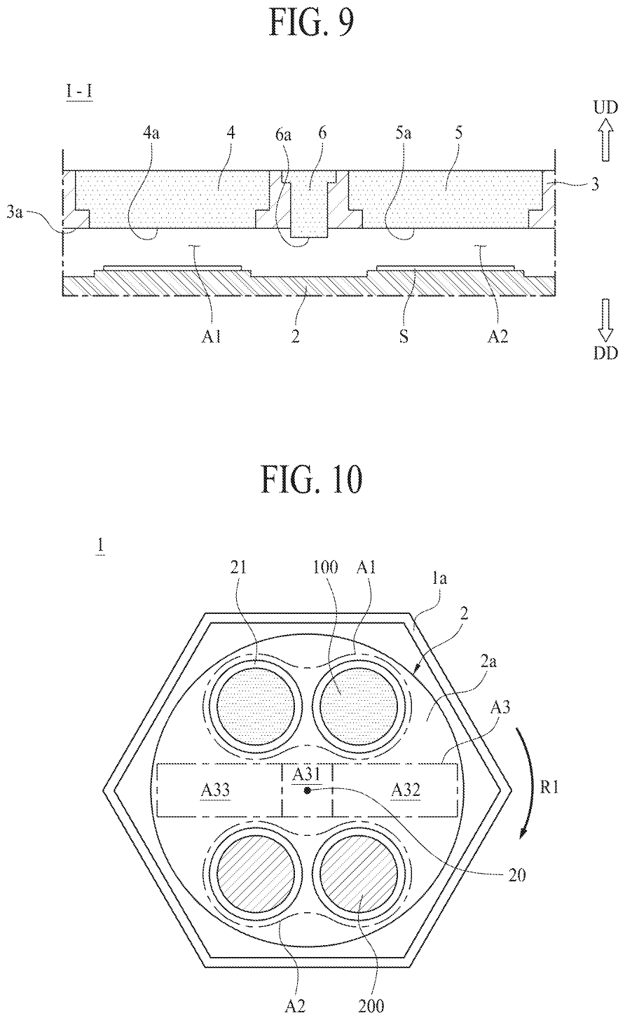

Referring to FIG. 9, the bottom surface 6a of the purge gas unit 6 may be disposed apart from the supporting unit 2 by a shorter distance than a distance by which the bottom surface 4a of the first gas injection unit 4 is apart from the supporting unit 2. Therefore, in the substrate processing apparatus 1 according to the present disclosure, the purge gas unit 6 may more protrude toward the supporting unit 2 than the first gas injection unit 4, thereby enhancing a division force, dividing the first region A1 and the second region A2 by using the purge gas unit 6, through a gas barrier using the purge gas and a physical barrier using the arrangement of the purge gas unit 6. Therefore, the substrate processing apparatus 1 according to the present disclosure may increase a preventive force which prevents the first gas injected into the first region A1 from being mixed with the second gas injected into the second region A2, thereby decreasing the degree to which film quality is degraded due to mixing of gases. The bottom surface 6a of the purge gas unit 6 may be disposed apart from the supporting unit 2 by a shorter distance than a distance by which the bottom surface 5a of the second gas injection unit 5 is apart from the supporting unit 2.

The bottom surface 6a of the purge gas unit 6 may be disposed to protrude from the bottom surface 3a of the lid 3 by a first protrusion distance. In this case, the bottom surface 4a of the first gas injection unit 4 may be disposed to protrude from the bottom surface 3a of the lid 3 by a second protrusion distance which is shorter than the first protrusion distance. Accordingly, in the substrate processing apparatus 1 according to the present disclosure, the purge gas unit 6 may more protrude toward the supporting unit 2 than the first gas injection unit 4, thereby enhancing a division force which divides the first region A1 and the second region A2 by using the purge gas unit 6. Although not shown, the bottom surface 5a of the second gas injection unit 5 may be disposed to protrude from the supporting unit 2 by a third protrusion distance which is shorter than the second protrusion distance.

The bottom surface 6a of the purge gas unit 6 and the bottom surface 4a of the first gas injection unit 4 may be disposed apart from the supporting unit 2 by the same distance. For example, the bottom surface 6a of the purge gas unit 6 and the bottom surface 4a of the first gas injection unit 4 may be disposed at the same height as the bottom surface 3a of the lid 3. The bottom surface 6a of the purge gas unit 6 and the bottom surface 5a of the second gas injection unit 5 may be disposed at the same height as the bottom surface 3a of the lid 3.

Referring to FIGS. 1 to 11, the rotation unit 7 (illustrated in FIG. 2) rotates the supporting unit 2. The rotation unit 7 may rotate the supporting unit 2 with respect to a rotation shaft 20 (illustrated in FIG. 10) of the supporting unit 2. The rotation unit 7 may rotate the supporting unit 2 in a first rotation direction (an R1 arrow direction) (illustrated in FIG. 10). The first region A1, the third region A3, the second region A2, and the third region A3 may be sequentially disposed along the first rotation direction (the R1 arrow direction). As the rotation unit 7 rotates the supporting unit 2, a substrate S (illustrated in FIG. 3) supported by the supporting unit 2 may rotate about the rotation shaft 20 of the supporting unit 2. Accordingly, the substrate S supported by the supporting unit 2 may sequentially move between the first region A1, the third region A3, and the second region A2.

In a case where the substrate processing apparatus 1 according to the present disclosure performs a processing on a plurality of substrates S in each of the first region A1 and the second region A2, the rotation unit 7 may operate as follows.

First, as illustrated in FIG. 10, the rotation unit 7 may rotate the supporting unit 2 so that a plurality of first substrates 100 are located in the first region A1 and a plurality of second substrates 200 are located in the second region A2.

Subsequently, when the first substrates 100 are located in the first region A1 and the plurality of second substrates 200 are located in the second region A2, the rotation unit 7 may stop the supporting unit 2.

Subsequently, the first gas injection unit 4 may inject the first gas into the first region A1. Therefore, an adsorption process of adsorbing the first gas onto the first substrates 100 may be performed in the first region A1. In this case, the second gas injection unit 5 may stand by without injecting the second gas into the second region A2.

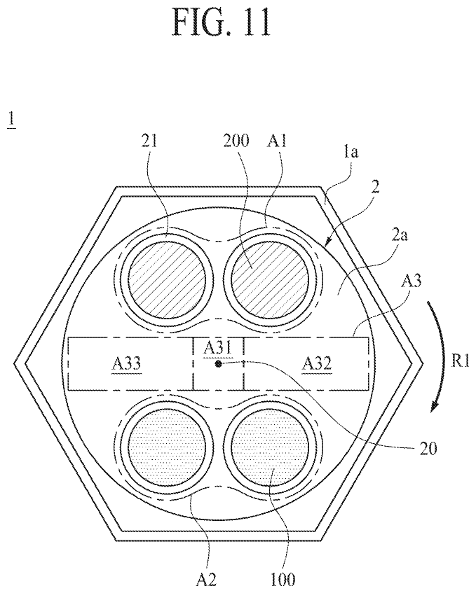

Subsequently, when the adsorption process performed on the first substrates 100 is completed, the rotation unit 7 may rotate the supporting unit 2 so that the second substrates 200 are located in the first region A1 and the first substrates 100 are located in the second region A2 as illustrated in FIG. 11. In this case, the first substrates 100 may pass through the third region A3 in a process of moving from the first region A1 to the second region A2. Therefore, a first gas which is not adsorbed onto the first substrates 100 may be removed by the purge gas injected by the purge gas unit 6. In this case, the second substrates 200 may pass through the third region A3 in a process of moving from the second region A2 to the first region A1.

Subsequently, when the second substrates 200 are located in the first region A1 and the first substrates 100 are located in the second region A2, the rotation unit 7 may stop the supporting unit 2.

Subsequently, the first gas injection unit 4 may inject the first gas into the first region A1. Therefore, an adsorption process of adsorbing the first gas onto the second substrates 200 may be performed in the first region A1. In this case, the second gas injection unit 5 may inject the second gas into the second region A2. Therefore, a deposition process of depositing a thin film on the first substrates 100 by reacting the first gas adsorbed onto the first substrates 100 with the second gas injected by the second gas injection unit 5 may be performed in the second region A2. Therefore, the thin film may be deposited on the first substrates 100 by an atomic layer deposition (ALD) process. Accordingly, the substrate processing apparatus 1 according to the present disclosure may be implemented so that the second region A2 is formed to have a greater size than that of the first region A1, and thus, a partial pressure difference between the first region A1 and the second region A2 is reduced even when the second gas is injected at a flow rate which is higher than that of the first gas. Therefore, the substrate processing apparatus 1 according to the present disclosure may implement a restraint force which prevents the second gas injected into the second region A2 from penetrating into the first region A1 and prevents the first gas injected into the first region A1 from penetrating into the second region A2. Accordingly, the substrate processing apparatus 1 according to the present disclosure may enhance a level of completion of a deposition process performed on the first substrates 100 and a level of completion of an adsorption process performed on the second substrates 200. The deposition process performed on the first substrates 100 and the adsorption process performed on the second substrates 200 may be performed simultaneously.

Subsequently, when the deposition process performed on the first substrates 100 and the adsorption process performed on the second substrates 200 are completed, the rotation unit 7 may rotate the supporting unit 2 so that the first substrates 100 are located in the first region A1 and the second substrates 200 are located in the second region A2 as illustrated in FIG. 10. In this case, the second substrates 200 may pass through the third region A3 in a process of moving from the first region A1 to the second region A2. Therefore, a first gas which is not adsorbed onto the second substrates 200 may be removed by the purge gas injected by the purge gas unit 6. In this case, the first substrates 100 may pass through the third region A3 in a process of moving from the second region A2 to the first region A1. Accordingly, a second gas which is not deposited on the first substrates 100 may be removed by the purge gas injected by the purge gas unit 6.

Subsequently, when the first substrates 100 are located in the first region A1 and the second substrates 200 are located in the second region A2, the rotation unit 7 may stop the supporting unit 2.

Subsequently, the first gas injection unit 4 may inject the first gas into the first region A1. Therefore, an adsorption process of adsorbing the first gas onto thin films deposited on the first substrates 100 may be performed in the first region A1. In this case, the second gas injection unit 5 may inject the second gas into the second region A2. Therefore, a deposition process of depositing a thin film on the second substrates 200 by reacting the first gas adsorbed onto the second substrates 200 with the second gas injected by the second gas injection unit 5 may be performed in the second region A2. Therefore, the thin film may be deposited on the second substrates 200 by an atomic layer deposition (ALD) process. Accordingly, the substrate processing apparatus 1 according to the present disclosure may be implemented so that the second region A2 is formed to have a greater size than that of the first region A1, and thus, a partial pressure difference between the first region A1 and the second region A2 is reduced even when the second gas is injected at a flow rate which is higher than that of the first gas. Therefore, the substrate processing apparatus 1 according to the present disclosure may implement a restraint force which prevents the first gas injected into the first region A1 from penetrating into the second region A2 and prevents the second gas injected into the second region A2 from penetrating into the first region A1. Accordingly, the substrate processing apparatus 1 according to the present disclosure may enhance a level of completion of a deposition process performed on the second substrates 200 and a level of completion of an adsorption process performed on the first substrates 100. The adsorption process performed on the first substrates 100 and the deposition process performed on the second substrates 200 may be performed simultaneously.

As described above, the rotation unit 7 may repeat a rotation of the supporting unit 2 and the stop of the rotation so that an adsorption process and a deposition process on the first substrates 100 and an adsorption process and a deposition process on the second substrates 200 are repeatedly performed. The rotation unit 7 may repeat a rotation of the supporting unit 2 and the stop of the rotation so that an adsorption process and a deposition process are performed on each of the first substrates 100 and the second substrates 200 a predetermined plurality of times. In this case, the number of adsorption processes and deposition processes performed on the first substrates 100 and the number of adsorption processes and deposition processes performed on the second substrates 200 may be implemented to be equal. To this end, finally, the second gas injection unit 5 may inject the second gas to the second substrates 200 in the second region A2, and in the first region A1, the first gas injection unit 4 may stand by without injecting the first gas to the first substrates 100.

As described above, the substrate processing apparatus 1 according to the present disclosure is implemented so that an adsorption process is performed in the first region A1 and a deposition process is performed in the second region A2, and thus, is implemented to deposit a thin film through an atomic layer deposition (ALD) process. In this case, the first region A1 and the second region A2 are divided by the purge gas injected into the third region A3, thereby preventing film quality from being degraded due to mixing of the first gas and the second gas. Furthermore, the substrate processing apparatus 1 according to the present disclosure is implemented so that the substrates 100 and 200 move between the first region A1 and the second region A2 through a rotation of the supporting unit 2, and simultaneously, the adsorption process and the deposition process are performed in a state where the rotation of the supporting unit 2 stops. Accordingly, the substrate processing apparatus 1 according to the present disclosure may enhance the stability of a process of depositing a thin film through an atomic layer deposition (ALD) process, thereby enhancing film quality.

When moving the first substrate 100 from the first region A1 to the second region A2, the rotation unit 7 may always rotate the supporting unit 2 at a constant fixed rotation angle with respect to the rotation shaft 20. When moving the first substrate 100 from the second region A2 to the first region A1, the rotation unit 7 may rotate the supporting unit 2 at a variable rotation angle varying with respect to the rotation shaft 20. For example, the fixed rotation angle may be 180 degrees, and the variable rotation angle may be an angle which differs from 180 degrees. The variable rotation angle may be 181 degrees, 179 degrees, or the like. In this case, the rotation unit 7 may repeat a rotation of the supporting unit 2 and the stop of the rotation in the order of 180 degrees, 179 degrees, 180 degrees, and 181 degrees. The rotation unit 7 may repeat a rotation of the supporting unit 2 and the stop of the rotation in the order of 180 degrees, 181 degrees, 180 degrees, and 179 degrees.

As described above, the substrate processing apparatus 1 according to the present disclosure is implemented so that the rotation unit 7 rotates the supporting unit 2 at the variable rotation angle, and thus, may change portions of the substrates 100 and 200 disposed at lower portions of the first injection holes in the first region A1 and disposed at lower portions of the second injection holes in the second region A2 whenever the supporting unit 2 rotates at the variable rotation angle. Therefore, the substrate processing apparatus 1 according to the present disclosure may decrease the degree of occurrence of a transfer phenomenon where a hole pattern caused by positions of the first injection holes and the second injection holes is transferred to a substrate on which the processing is completed, thereby enhancing the uniformity of the processing.

Here, the purge gas unit 6 may include a plurality of purge holes 61 (illustrated in FIG. 8) and a purge body 62 (illustrated in FIG. 8).

The purge holes 61 inject the purge gas. The purge holes 61 may be formed in the purge body 62. The purge holes 61 may be disposed apart from one another.

The purge body 62 may be coupled to the lid 3. The purge body 62 may be disposed apart from the third region A3 in the upward direction (the UD arrow direction).

Referring to FIG. 8, the purge body 62 may include a first purge body 621, a second purge body 622, and a third purge body 623.

The first purge body 621 is disposed between the second purge body 622 and the third purge body 623. The first purge body 621 may be disposed to correspond to a center region A31 (illustrated in FIG. 8) of the third region A3. The first purge body 621 may inject the purge gas into the center region A31 through the purge holes 61. The center region A31 may be disposed between one region A32 (illustrated in FIG. 10) of the third region A3 and the other region A33 (illustrated in FIG. 10) of the third region A3. The one region A32 is a region through which the substrates 100 and 200 pass in moving from the first region A1 to the second region A2. The other region A33 is a region through which the substrates 100 and 200 pass in moving from the second region A2 to the first region A1.

The second purge body 622 is disposed to correspond to the one region A32. The second purge body 622 may inject the purge gas into the one region A32 through the purge holes 61. A plasma generating mechanism 63 (illustrated in FIG. 8) may be coupled to the second purge body 622. The plasma generating mechanism generates plasma. Therefore, in a process of moving the substrates 100 and 200 from the first region A1 to the second region A2, injection of the purge gas to the substrates 100 and 200 and plasma processing performed on the substrates 100 and 200 may be simultaneously performed in the one region A32. The second purge body 622 may activate the purge gas by using the plasma and may inject the activated purge gas into the one region A32. In this case, processing based on the activated purge gas may be performed on the substrates 100 and 200 in the one region A32. In this case, the second purge body 622 coupled to the plasma generating mechanism 63 may be implemented as a showerhead type illustrated in FIG. 6 or an electrode structure type illustrated in FIG. 7.

The third purge body 623 may be disposed to correspond to the other region A33. The third purge body 623 may inject the purge gas into the other region A33 through the purge holes 61. A window 64 (illustrated in FIG. 8) may be coupled to the third purge body 623. A temperature measurement unit (not shown) may measure, through the window 64, a temperature of each of the substrates 100 and 200 passing through the other region A33. The window 64 may be formed of a transparent material or a semitransparent material. Therefore, in a process of moving the substrates 100 and 200 from the second region A2 to the first region A1, injection of the purge gas to the substrates 100 and 200 and temperature measurement performed on the substrates 100 and 200 may be simultaneously performed in the other region A33.

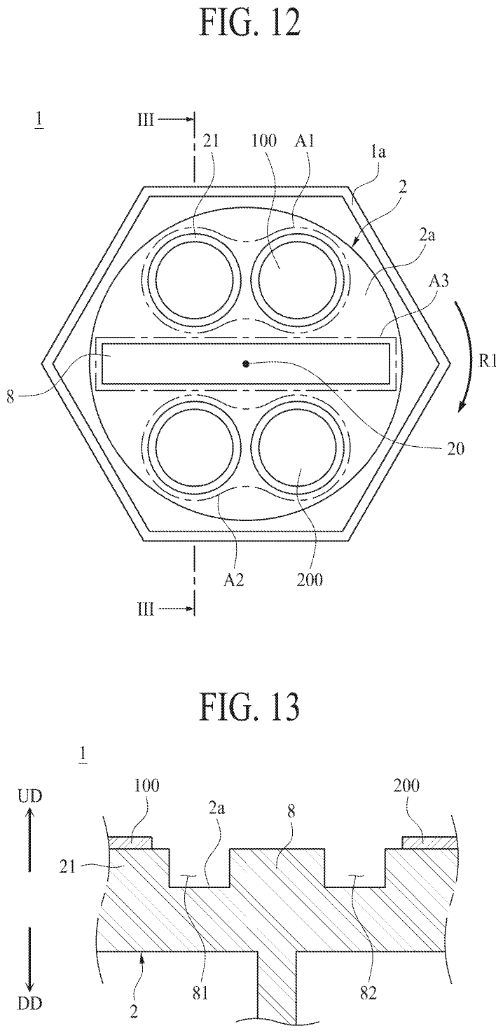

Referring to FIGS. 12 and 13, the substrate processing apparatus 1 according to the present disclosure may include a protrusion member 8.

The protrusion member 8 protrudes from the top surface 2a of the supporting unit 2 in the upward direction (the UD arrow direction). The protrusion member 8 may be disposed to correspond to the third region A3. Therefore, the substrate processing apparatus 1 according to the present disclosure may more reinforce a preventive force which prevents the first gas and the second gas from being mixed, through a gas barrier using the purge gas and a physical barrier using the protrusion member 8. The protrusion member 8 may protrude from the top surface 2a of the supporting unit 2 in the upward direction (the UD arrow direction) so that a top surface thereof is disposed at the same height as a top surface of the mounting member 21. The protrusion member 8 may be formed in a wholly rectangular shape, but is not limited thereto and may be formed in another shape such as a discal shape for implementing a physical barrier between the first region A1 and the second region A2. The protrusion member 8 and the supporting unit 2 may be provided as one body. The protrusion member 8 may be disposed at a position apart from the mounting member 21.

As the protrusion member 8 and the mounting members 21 protrude from the top surface 2a of the supporting unit 2 in the upward direction (the UD arrow direction), a first gas groove 81 (illustrated in FIG. 13) may be formed between the first region A1 and the third region A3. The first gas groove 81 may be implemented in a shape, such as a valley, between the protrusion member 8 and the mounting members 21. Therefore, a residual gas including at least one of the purge gases injected by the purge gas unit 6 and the first gas injected by the first gas injection unit 4 may flow along the first gas groove 81 and may be exhausted to the outside of the chamber 1a. A second gas groove 82 (illustrated in FIG. 13) may be formed between the second region A2 and the third region A3. The second gas groove 82 may be implemented in a shape, such as a valley, between the protrusion member 8 and the mounting members 21. Therefore, a residual gas including at least one of the purge gases injected by the purge gas unit 6 and the second gas injected by the second gas injection unit 5 may flow along the second gas groove 82 and may be exhausted to the outside of the chamber 1a.

Therefore, the substrate processing apparatus 1 according to the present disclosure is implemented to smoothly exhaust a residual gas through the gas grooves 81 and 82. Also, since the protrusion member 8 and the mounting members 21 protrude from the top surface 2a of the supporting unit 2 in the upward direction (the UD arrow direction), the substrate processing apparatus 1 according to the present disclosure is implemented to prevent a residual gas exhausted through the gas grooves 81 and 82 from penetrating toward the substrates 100 and 200. In this case, an outer surface, facing the gas grooves 81 and 82, of each of the protrusion member 8 and the mounting members 21 may function as a barrier which prevents a residual gas from penetrating toward the substrates 100 and 200. Accordingly, the substrate processing apparatus 1 according to the present disclosure may decrease the degree of partial occurrence of a deviation, caused by a residual gas, of a processing rate such as a deposition rate or an etching rate in the substrates 100 and 200, thereby more enhancing the uniformity of a processing.

The present disclosure described above are not limited to the above-described embodiments and the accompanying drawings and those skilled in the art will clearly appreciate that various modifications, deformations, and substitutions are possible without departing from the scope and spirit of the invention.

1. An apparatus for processing substrate, the apparatus comprising:
a supporting unit for supporting a substrate;
a lid disposed apart from the supporting unit in an upward direction;
a first gas injection unit coupled to the lid to inject a first gas into a first region;
a second gas injection unit coupled to the lid to inject a second gas into a second region;
a purge gas unit coupled to the lid to inject a purge gas into a third region disposed between the first region and the second region; and
a rotation unit for rotating the supporting unit,
wherein
the rotation unit rotates the supporting unit, so that the substrate is moved between the first region and the second region, and stops the rotation of the supporting unit while a processing using the first gas is being performed in the first region and a processing using the second gas is being performed in the second region, and
a distance by which a bottom surface of the first gas injection unit is disposed apart from the supporting unit is shorter than a distance by which a bottom surface of the second gas injection unit is apart from the supporting unit.

2. The apparatus of claim 1, wherein
the bottom surface of the second gas injection unit is disposed apart from a bottom surface of the lid in the upward direction, and
the bottom surface of the first gas injection unit is disposed apart from the bottom surface of the lid in a downward direction opposite to the upward direction.

3. The apparatus of claim 1, wherein the bottom surface of the second gas injection unit is disposed apart from the supporting unit by a distance which is 3 to 15 times a distance by which the bottom surface of the first gas injection unit is apart from the supporting unit.

4. The apparatus of claim 1, wherein the first gas injection unit injects the first gas into the first region having a less volume than a volume of the second region into which the second gas injection unit injects the second gas.

5. The apparatus of claim 1,
wherein the first gas injection unit comprises:
a module body coupled to the lid; and
a plurality of first injection holes provided in the module body to inject the first gas into the first region, and
wherein the second gas injection unit comprises:
a first electrode where a plurality of second injection holes injecting the second gas are formed, the first electrode being coupled to a plurality of protrusion electrodes; and
a second electrode where a plurality of openings are provided at positions corresponding to the plurality of protrusion electrodes.

6. The apparatus of claim 5, wherein the second gas injection unit injects the second gas into a separation space between the first electrode and the second electrode.

7. The apparatus of claim 1, wherein a bottom surface of the purge gas unit is disposed apart from the supporting unit by a shorter distance than a distance by which the bottom surface of the first gas injection unit is apart from the supporting unit.

8. The apparatus of claim 1, wherein a bottom surface of the purge gas unit and the bottom surface of the first gas injection unit are disposed apart from the supporting unit by the same distance.

9. The apparatus of claim 1, wherein the supporting unit comprises a mounting member protruding from a top surface of the supporting unit in the upward direction, for placing a top surface of the substrate at a position apart from the top surface of the supporting unit.

10. The apparatus of claim 1, further comprising a protrusion member disposed in the third region to protrude from a top surface of the supporting unit in the upward direction.

11. The apparatus of claim 10, wherein the protrusion member comprises:
a first gas groove provided between the first region and the third region; and
a second gas groove provided between the first region and the second region.

12. The apparatus of claim 1, further comprising a protrusion member disposed in the third region to protrude from a top surface of the supporting unit in the upward direction,
wherein
the supporting unit comprises a mounting member disposed apart from the protrusion member to protrude from the top surface of the supporting unit in the upward direction,
the protrusion member comprises a first gas groove provided between the first region and the third region, and a second gas groove provided between the first region and the second region, and
the protrusion member and the mounting member each comprise an outer surface facing the first gas grooves and the second gas groove.

13. The apparatus of claim 1, wherein
the purge gas unit comprises a purge body disposed apart from the third region in the upward direction and coupled to the lid,
the purge body comprises a first purge body disposed to correspond to a center region of the third region, and a second purge body disposed in one region of the third region through which the substrate passes in moving from the first region to the second region, and
a plasma generating mechanism generating plasma is coupled to the second purge body.

14. The apparatus of claim 1, wherein
the purge gas unit comprises a purge body disposed apart from the third region in the upward direction and coupled to the lid,
the purge body comprises a first purge body disposed to correspond to a center region of the third region, and a third purge body disposed in the other region of the third region through which the substrate passes in moving from the second region to the first region, and
a window for measuring a temperature of the substrate passing through the other region is coupled to the third purge body.

15. The apparatus of claim 1, wherein the rotation unit rotates the supporting unit at a fixed rotation angle with respect to a rotation shaft of the supporting unit in moving the substrate from the first region to the second region and rotates the supporting unit at a variable rotation angle differing from the fixed rotation angle in moving the substrate from the second region to the first region.

16. The apparatus of claim 1,
wherein the first gas injection unit comprises:
a plurality of first injection modules injecting the first gas into the first region where a plurality of substrates are disposed;
a first injection body coupled to the plurality of first injection modules; and
a first sealing member for sealing a gap between the first injection body and the lid, and
wherein the first sealing member is disposed to surround outer portions of the plurality of first injection modules.
